(19) United States
(12) Patent Application Publication
(10) Pub. No.: US 2014/0346578 A1
(43) Pub. Date: Nov. 27, 2014

(54) SOLID-STATE IMAGE SENSOR, METHOD OF MANUFACTURING THE SAME, AND IMAGE CAPTURING SYSTEM

(71) Applicant: CANON KABUSHIKI KAISHA, Tokyo (JP)

(72) Inventor: Katsunori Hirota, Yamato-shi (JP)

(73) Assignee: CANON KABUSHIKI KAISHA, Tokyo (JP)

(21) Appl. No.: 14/274,055

(22) Filed: May 9, 2014

(30) Foreign Application Priority Data
May 23, 2013 (JP) 2013-109387

(51) Int. Cl. H01L 27/146

(52) U.S. Cl. CPC H01L 27/14689; H01L 27/14612
USPC 257/292; 438/73

(57) ABSTRACT

A solid-state image sensor including a pixel unit arranged on a semiconductor substrate and including a plurality of photoelectric converters, and a peripheral circuit unit arranged on the semiconductor substrate and including MOS transistors and a capacitive element portion, wherein a gate insulating film of the MOS transistor in the peripheral circuit unit and an insulating film between facing electrodes of the capacitive element portion are nitrided, and a density of nitrogen atoms in the nitrided insulating film of the capacitive element portion is higher than the density of the nitrogen atoms in the nitrided insulating film of the MOS transistor in the peripheral circuit unit.

### BACKGROUND OF THE INVENTION

1. Field of the Invention

The present invention relates to a solid-state image sensor, a method of manufacturing the same, and an image capturing system.

2. Description of the Related Art

There is a solid-state image sensor such as a CMOS sensor including a pixel unit and a peripheral circuit unit including peripheral circuits configured to process the electrical signal from a pixel unit. The pixel unit includes a photoelectric converter provided on a semiconductor substrate and configured to convert light into charges, and an amplification MOS transistor that outputs a signal corresponding to the charges in the photoelectric converter to a column signal line. The peripheral circuit unit includes a circuit that drives pixels or process a signal output to a column signal line. In a MOS transistor of the peripheral circuit unit, the gate insulating film is thinned to improve the driving capability and achieve speedup. However, when the gate insulating film is thinned, boron in the gate electrode diffuses into the silicon substrate due to heat applied in various heat treatment processes after the gate electrode formation, and the leakage current increases. Japanese Patent Laid-Open Nos. 2004-296603 and 2004-342656 describe methods of suppressing degradation in characteristic by introducing nitrogen into the gate insulating film. However, when the gate insulating film is nitrided, the interface state of the interface between the gate insulating film and the semiconductor substrate increases, resulting in 1/f noise. More specifically, when the gate insulating film is nitrided, a level is formed in the energy gap of the gate insulating film by the introduced nitrogen. For this reason, 1/f noise is generated due to exchange of charges between the level and the channel of the MOS transistor. Japanese Patent Laid-Open No. 2007-317741 discloses a solid-state image sensor including a nitrided gate insulating film and an unnitrided gate insulating film so as to implement reduction of 1/f noise and a method of manufacturing the same. Some solid-state image sensors incorporate a memory. However, since the chip area increases due to the area of a capacitor included in the memory, and the number of chips per wafer decreases, cost reduction of chips is impeded. Japanese Patent Laid-Open No. 2005-347655 discloses a method of thinning the insulating film of a capacitor and forming an insulating film using a substance having a high dielectric constant such as a silicon nitride film.

### SUMMARY OF THE INVENTION

The first aspect of the present invention provides a solid state image sensor comprising a pixel unit arranged on a semiconductor substrate and including a plurality of photoelectric converters, and a peripheral circuit unit arranged on the semiconductor substrate and including MOS transistors and a capacitive element portion, wherein a gate insulating film of the MOS transistor in the peripheral circuit unit and an insulating film between facing electrodes of the capacitive element portion are nitrided, and a density of nitrogen atoms in the nitrided insulating film of the capacitive element portion is higher than the density of the nitrogen atoms in the nitrided insulating film of the MOS transistor in the peripheral circuit unit.

The second aspect of the present invention provides a solid-state image sensor comprising a pixel unit arranged on a semiconductor substrate and including a plurality of photoelectric converters, and a peripheral circuit unit arranged on the semiconductor substrate and including MOS transistors and a capacitive element portion, wherein a gate insulating film of the MOS transistor in the peripheral circuit unit and an insulating film between facing electrodes of the capacitive element portion are nitrided, the gate insulating film of the MOS transistor in the pixel unit is not nitrided, and a density of nitrogen atoms in the nitrided insulating film of the capacitive element portion is higher than the density of the nitrogen atoms in the nitrided insulating film of the MOS transistor in the peripheral circuit unit.

The third aspect of the present invention provides a method of manufacturing a solid-state image sensor comprising a pixel unit arranged on a semiconductor substrate and including a plurality of photoelectric converters, and a peripheral circuit unit arranged on the semiconductor substrate and including MOS transistors and a capacitive element portion, the method comprising forming a lower electrode by implanting an impurity into a region of the semiconductor substrate where the capacitive element portion should be formed, forming an insulating film covering a region of the semiconductor substrate where a pixel region should be formed and a region where a peripheral circuit region should be formed, selectively nitriding the insulating film in the region where the capacitive element portion should be formed, and selectively nitriding the insulating film in the region where the capacitive element portion should be formed and the region where the peripheral circuit unit should be formed.

The fourth aspect of the present invention provides an image capturing system comprising above solid-state image sensor and a signal processing circuit configured to process an output signal from the solid-state image sensor.

Further features of the present invention will become apparent from the following description of exemplary embodiments (with reference to the attached drawings)

### BRIEF DESCRIPTION OF THE DRAWINGS

FIG. 1 is a view showing the arrangement of a solid-state image sensor 800 according to an embodiment;

FIG. 2 is a sectional view showing the sectional structure of the solid-state image sensor 800 according to the embodiment;

FIGS. 3A to 3G are sectional views showing the sectional structure of the solid-state image sensor 800 according to the embodiment;

FIGS. 4A and 4B are sectional views showing steps in the manufacture of a solid-state image sensor 800 according to the second embodiment; and

FIG. 5 is a block diagram showing the arrangement of an image capturing system to which the solid-state image sensor according to the present invention is applied.

### DESCRIPTION OF THE EMBODIMENTS

In an image sensor including a capacitive element provided in a peripheral circuit unit, the leakage current may increase when the gate insulating film of a MOS transistor in the peripheral circuit unit is thinned. In addition, when a gate electrode contains boron, degradation in characteristics may occur, for example, the boron in the gate electrode may diffuse in the silicon substrate. In addition, the capacitive element have a large area in a chip.

The present invention has been made in consideration of the above-described problems, and provides a solid-state image sensor capable of increasing the capacitance of a capacitive element portion per area while suppressing degradation in characteristic of MOS transistors in a peripheral circuit unit and a method of manufacturing the same.

### First Embodiment

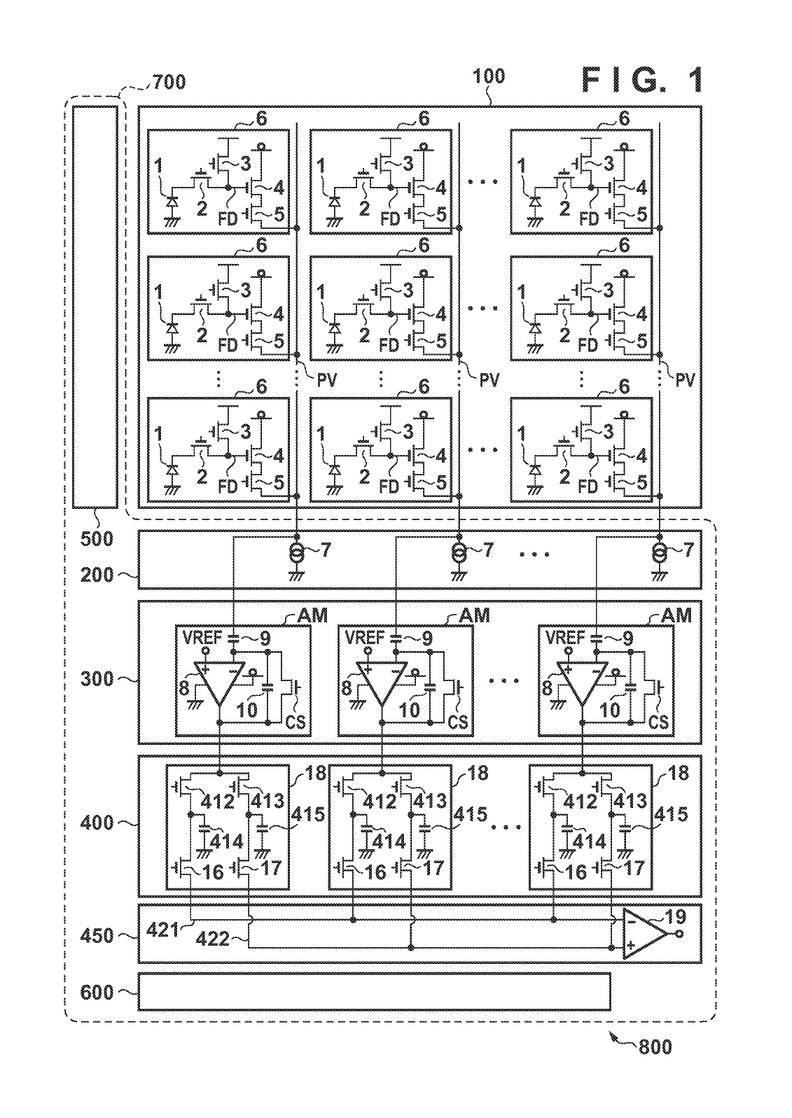

The schematic arrangement of a solid-state image sensor 800 according to an embodiment of the present invention will be described with reference to FIG. 1. The solid-state image sensor 800 includes a pixel unit 100 and a peripheral circuit unit 700. The pixel unit 100 is a region where a plurality of pixels are arranged. The peripheral circuit unit 700 is a region arranged in the periphery of the pixel unit 100, where a plurality of control circuits configured to control the plurality of pixels and peripheral circuits serving as a signal read path are arranged.

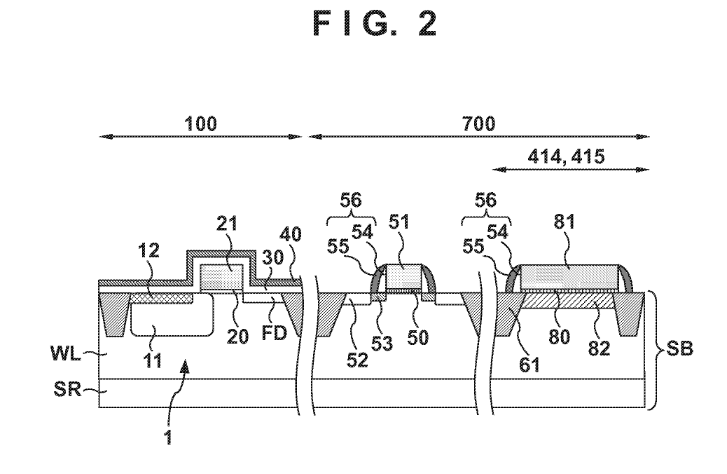

In the pixel unit 100, a plurality of pixels 6 are arranged in the row and column directions. Each pixel 6 includes a photoelectric converter 1, a transfer transistor 2, a charge-voltage converter FD, a reset portion 3, an output portion 4, and a selector 5. The photoelectric converter 1 generates and accumulates charges (signal) corresponding to light. The photoelectric converter 1 is, for example, a photodiode. As shown in FIG. 2, the photoelectric converter 1 includes a charge accumulation region 11 configured to accumulate charges, and a protection region 12 formed on the upper surface side of a semiconductor substrate to protect the charge accumulation region 11. The transfer transistor 2 is turned on so as to transfer the charges in the charge accumulation region 11 to the charge-voltage converter FD when a transfer control signal of active level is supplied from a vertical scanning circuit 500 to the gate. The charge-voltage converter FD converts the charges transferred from the charge accumulation region 11 into a voltage. The charge-voltage converter FD is, for example, a floating diffusion. The reset portion 3 is, for example, a reset transistor which is turned on so as to reset the charge-voltage converter FD when a reset control signal of active level is supplied from the vertical scanning circuit 500 to the gate.

The output portion 4 outputs a signal corresponding to the voltage of the charge-voltage converter FD. The output portion 4 is, for example, an amplification transistor. The amplification transistor performs a source follower operation together with a constant current source 7 connected to a column signal line PV, thereby outputting a signal corresponding to the voltage of the charge-voltage converter FD to the column signal line PV. The selector 5 is, for example, a select transistor. The select transistor is turned on so as to set the pixel 6 in a selected state when a transfer control signal of active level is supplied from the vertical scanning circuit 500 to the gate. When the pixel 6 is selected, the output signal from the output portion 4 is output to the column signal line PV. In addition, the selector 5 is turned off so as to set the pixel 6 in an unselected state when a transfer control signal of inactive level is supplied from the vertical scanning circuit 500 to the gate. In a state in which the pixel 6 is selected, and the charge-voltage converter FD is reset by the reset portion 3, the output portion 4 outputs a signal, that is, a noise signal corresponding to the reset voltage of the charge-voltage converter FD to the column signal line PV. When the charges in the charge accumulation region 11 are transferred to the charge-voltage converter FD by the transfer transistor 2 in a state in which the pixel 6 is selected, the output portion 4 outputs a signal from the photoelectric converter 1, which is converted into a voltage by the charge-voltage converter FD, to the column signal line PV.

The vertical scanning circuit 500, a constant current source block 200, a column amplifier block 300, a holding capacitor block 400, a horizontal scanning circuit 600, and an output amplifier block 450 are arranged in the peripheral circuit unit 700. The vertical scanning circuit 500 scans the pixel unit 100 in the vertical direction, selects a row (read row) to read signals, and controls the pixels so as to read signals from the selected read row. The vertical scanning circuit 500 includes a plurality of MOS transistors. The constant current source block 200 includes a plurality of constant current sources 7 corresponding to a plurality of column signal lines PV connected to a plurality of columns of the pixel unit 100. The constant current source block 200 includes, for example, a MOS transistor. The column amplifier block 300 includes a plurality of column amplifier units AM corresponding to the plurality of column signal lines PV. The plurality of column amplifier units AM are arranged in the row direction. Each column amplifier unit AM includes, for example, a differential amplifier 8, a clamp capacitor 9, a feedback capacitor 10, and a clamp control switch CS. Each column amplifier unit AM can output the offset of the differential amplifier 8 as a first signal. In addition, each column amplifier unit AM can perform a clamp operation, thereby outputting a signal obtained by superimposing the offset of the differential amplifier 8 on the differential signal between an optical signal and a noise signal as a second signal. The clamp control switch CS includes, for example, a MOS transistor.

The holding capacitor block 400 includes a plurality of column signal holding units 18 corresponding to the plurality of column amplifier units AM. The plurality of column signal holding units 18 are arranged in the row direction. Each column signal holding unit 18 includes a first write transistor 412, a second write transistor 413, a first holding capacitor 414, a second holding capacitor 415, a first transfer transistor 16, and a second transfer transistor 17. When on-controlled, the first write transistor (MOS transistor) 412 writes the first signal output from the column amplifier unit AM in the first holding capacitor 414. After that, when the first write transistor 412 is off-controlled, the first holding capacitor 414 holds the first signal. When on-controlled, the second write transistor (MOS transistor) 413 writes the second signal output from the column amplifier unit AM in the second holding capacitor 415. After that, when the second write transistor 413 is off-controlled, the second holding capacitor 415 holds the second signal. When on-controlled, the first transfer transistor (MOS transistor) 16 transfers the first signal held by the first holding capacitor 414 to an output amplifier 19 via a first output line 421. When on-controlled, the second transfer transistor (MOS transistor) 17 transfers the second signal held by the second holding capacitor 415 to the output amplifier 19 via a second output line 422.

The horizontal scanning circuit 600 supplies a control signal for scanning in the horizontal direction to the holding capacitor block 400 so that the signals of the columns of a read row held by the holding capacitor block 400 are sequentially transferred to the output amplifier 19. More specifically, the horizontal scanning circuit 600 sequentially turns on the first transfer transistor 16 and the second transfer transistor 17 of each column to output the first signal and the second signal respectively held by the first holding capacitor 414 and the second holding capacitor 415 to the output amplifier block 450.

The output amplifier block 450 includes the first output line 421, the second output line 422, and the output amplifier 19. The output amplifier 19 performs CDS processing of calculating the difference between the first signal transferred via the first output line 421 and the second signal transferred via the second output line 422, thereby generating and outputting an image signal. The output amplifier 19 includes, for example, a plurality of MOS transistors.

The sectional structure of the solid-state image sensor 800 according to this embodiment will be described next with reference to FIG. 2. The solid-state image sensor 800 includes a semiconductor substrate SB, a gate insulating film 20, a gate electrode 21, a gate insulating film 50, a gate electrode 51, an insulating film 80, an electrode 81, an insulating film 30, an insulating film 40, and a side wall spacer 56 including insulating films 54 and 55.

The semiconductor substrate SB includes a semiconductor region SR, a well WL, an element isolation portion 61, the photoelectric converter 1, the charge-voltage converter FD, a semiconductor region 52, an LDD region 53, the electrode 81, the insulating film 80, and an electrode 82. The electrode 82 is formed as a region containing an impurity at a higher concentration than the well WL. The electrode 81, the insulating film 80, and the electrode 82 facing the electrode 81 while sandwiching the insulating film 80 between them form a capacitive element portion. In the following description, the electrode 81 is an upper electrode, and the electrode 82 is a lower electrode. The semiconductor region SR, the well WL, and the element isolation portion 61 are arranged in the pixel unit 100, the peripheral circuit unit 700, and the regions of the holding capacitors 414 and 415 serving as a capacitive element portion. The photoelectric converter 1 and the charge-voltage converter FD are arranged in the pixel unit 100. The semiconductor region 52 and the LDD region 53 are arranged in the peripheral circuit unit 700. The upper electrode 81 and the lower electrode 82 are arranged in the holding capacitors 414 and 415 serving as a capacitive element portion.

The semiconductor region SR is formed in deep position from the surface of the semiconductor substrate SB. The semiconductor region SR contains an impurity (for example, phosphorus) of a first conductivity type (for example, n type) at a low concentration. The well WL is arranged on the semiconductor region SR of the semiconductor substrate SB. The well WL is a region formed by, for example, implanting an impurity (for example, boron) of a second conductivity type (for example, p type) opposite to the semiconductor region SR of the first conductivity type. The element isolation portion 61 is arranged to isolate a plurality of elements (for example, the photoelectric converter 1 and other MOS transistors in the peripheral circuit unit) on the semiconductor. The element isolation portion 61 has, for example, an STI element isolation structure or LOCOS element isolation structure. The photoelectric converter 1 includes the charge accumulation region 11 and the protection region 12. The charge accumulation region 11 is a region to accumulate charges, and contains the impurity (for example, phosphorus) of the first conductivity type (for example, n type) at a concentration higher than the well WL. The protection region 12 is arranged on the charge accumulation region 11 of the semiconductor substrate SB so as to protect the charge accumulation region 11. The protection region 12 contains the impurity (for example, boron) of the second conductivity type (for example, p type) at a concentration higher than the charge accumulation region 11 or the well WL. A photodiode having a buried structure is thus formed, and a dark current generated from the surface of the semiconductor substrate SB can be reduced.

The charge-voltage converter FD is a region to temporarily hold charges transferred from the charge accumulation region 11 and convert them into a voltage, and contains the impurity (for example, phosphorus) of the first conductivity type (for example, n type) at a concentration higher than the well WL.

The semiconductor region 52 contains the impurity (for example, phosphorus) of the first conductivity type (for example, n type) at a concentration higher than the well WL. The semiconductor region 52 functions as the source electrode or drain electrode of the MOS transistor. The semiconductor region 52 is formed by self alignment using the gate electrode 51 and the side wall spacer 56 as a mask, as will be described later.

The LDD region 53 is a field to reduce the electric field between the gate electrode 51 and the semiconductor region 52 when a voltage is applied to the gate electrode 51, and contains the impurity of the first conductivity type at a concentration lower than the semiconductor region 52. The LDD region 53 is formed by self alignment using the gate electrode 51 as a mask, as will be described later.

The lower electrode 82 forms an electrode of the capacitive element portion configured to hold a signal provided from the column signal line, and contains the impurity (for example, phosphorus) of the first conductivity type (for example, n type) at a concentration higher than the well WL. The lower electrode 82 is arranged so as to be sandwiched between the element isolation portions 61.

The gate insulating film 20 is arranged on the surface of the semiconductor substrate SB in the pixel unit 100. The gate insulating film 20 is, for example, a silicon oxide film. The gate electrode 21 is arranged on the gate insulating film 20. The gate electrode 21 is the gate electrode of the transfer transistor 2. No side wall spacer is arranged at a position adjacent to the side surface of the gate electrode 21.

The gate insulating film 50 is arranged on the surface of the semiconductor substrate SB in the peripheral circuit unit 700. The gate insulating film 50 is, for example, a nitrided silicon oxynitride film. The gate electrode 51 is arranged on the gate insulating film 50. The gate electrode 51 is the gate electrode of the above-described MOS transistor. The side wall spacer 56 is arranged at a position adjacent to the side surface of the gate electrode 51. The insulating film 80 is arranged on the surface of the lower electrode 82. The insulating film 80 is, for example, a nitrided silicon oxynitride film, and contains nitrogen atoms at a density higher than the gate insulating film 50. The upper electrode 81 is arranged so as to face the lower electrode 82. The insulating film 80 is sandwiched between the electrodes of the upper electrode 81 and the lower electrode 82. The upper electrode 81 and the lower electrode 82 are electrodes for the holding capacitors 414 and 415. The side wall spacer 56 is arranged at a position adjacent to the side surface of the upper electrode 81.

The insulating film 30 extends so as to cover the semiconductor substrate SB and the gate electrode 21 in the pixel unit 100. The insulating film 30 is not arranged in the peripheral circuit unit 700 and the holding capacitors 414 and 415. The insulating film 30 is formed from, for example, a silicon nitride film. The insulating film 40 extends so as to cover the insulating film 30 in the pixel unit 100. The insulating film 40 is not arranged in the peripheral circuit unit 700 and the holding capacitors 414 and 415. The insulating film 40 is formed from, for example, a silicon oxide film.

The side wall spacers 56 are arranged on the surface of the semiconductor substrate SB in the peripheral circuit unit 700 and the holding capacitors 414 and 415 at positions adjacent to the side surfaces of the gate electrode 51 and the upper electrode 81. Each side wall spacer 56 includes the first film 54 and the second film 55. The first film 54 is arranged to be adjacent to each of the side surface of the gate electrode 51 and the side surface of the upper electrode 81. The second film 55 is arranged to be adjacent to the first film 54. The first film 54 is made of the same material as the insulating film 30, and is formed from, for example, a silicon nitride film. The second film 55 is made of the same material as the insulating film 40, and is formed from, for example, a silicon oxide film. Note that a film formed from a silicon oxide film may be provided between the insulating film 30 and the semiconductor substrate SB and the gate electrode 21 and between the first film 54 and the gate electrode 51.

In the solid-state image sensor 800, since the gate insulating film 20 of the MOS transistor of the transfer transistor 2 in the pixel unit 100 is formed from an unnitrided silicon oxide film, 1/f noise can be suppressed. In addition, since the gate insulating film 50 of the MOS transistor in the peripheral circuit unit 700 is formed from a nitrided silicon oxynitride film, the driving capability of the MOS transistor can be improved by thinning the film while suppressing degradation in characteristic. Furthermore, since a nitride film has a dielectric constant higher than that of a silicon oxide film, the electrical film thickness decreases, and the driving capacity further improves. The insulating film 80 of the holding capacitors 414 and 415 is formed from a silicon oxynitride film nitrided higher than the gate insulating film of the MOS transistor in the peripheral circuit unit 700, thereby increasing the capacitance per area. It is therefore possible to reduce the area of the holding capacitors 414 and 415 in the image capturing device.

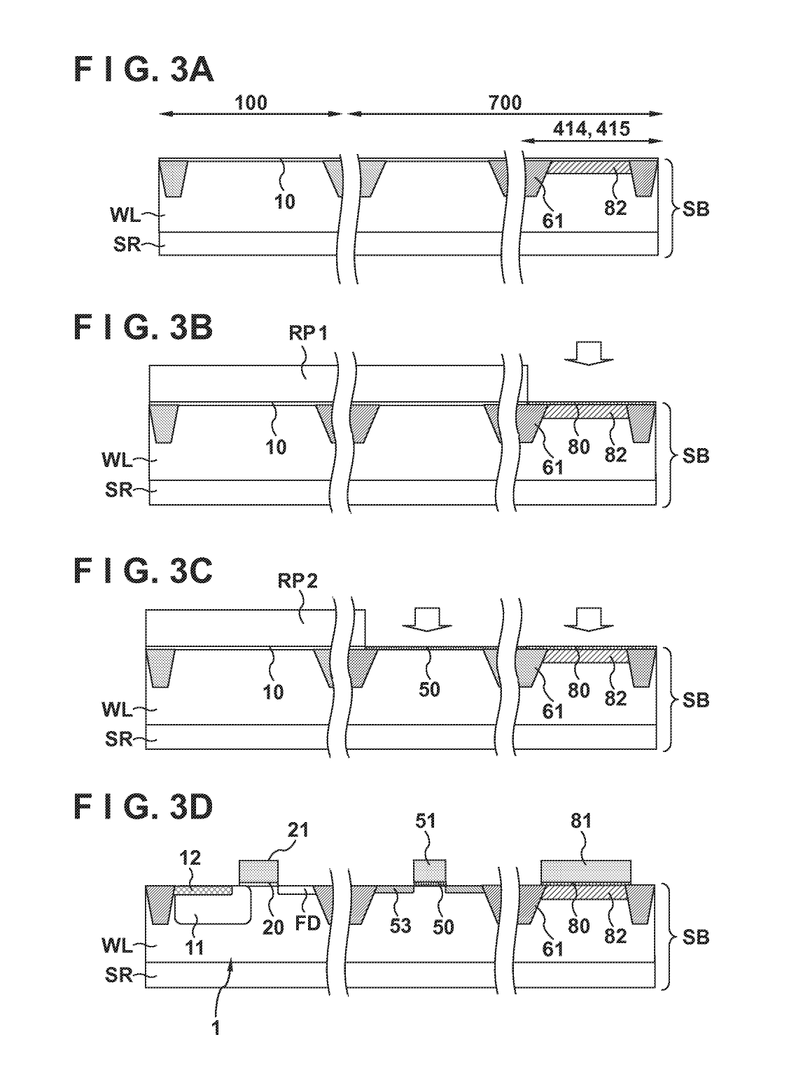

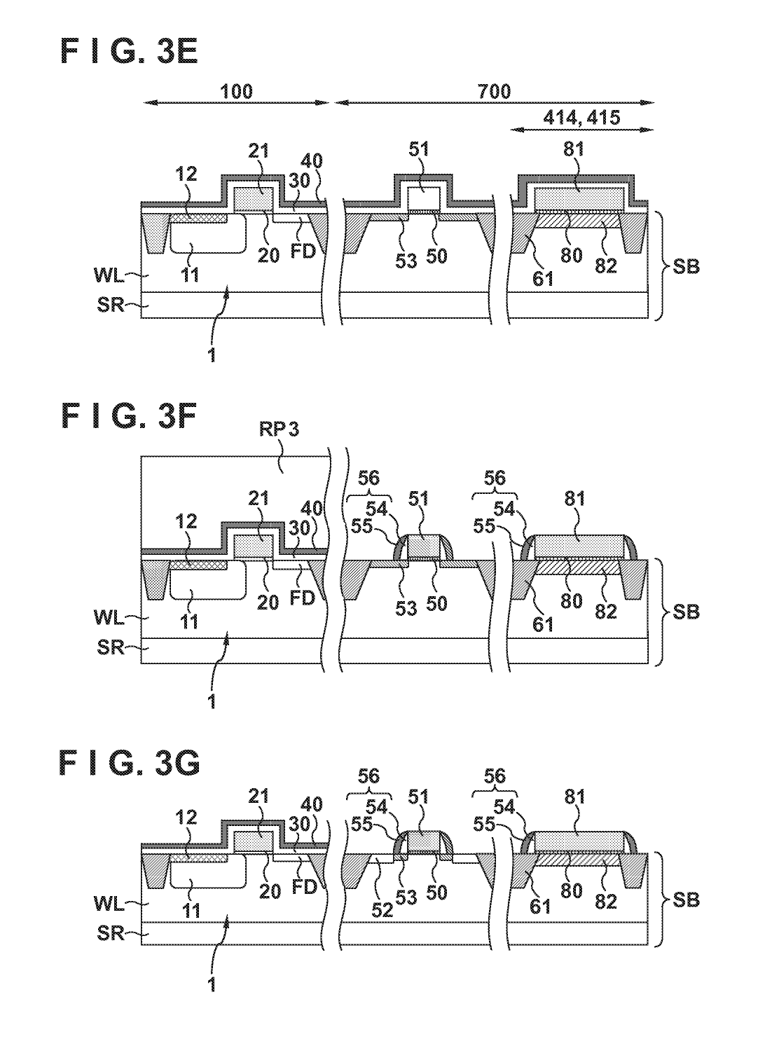

A method of manufacturing a solid-state image sensor 800 according to this embodiment will be described next with reference to FIGS. 3A to 3G. First, in the step shown in FIG. 3A, an element isolation portion 61 is formed in a semiconductor substrate SB of the first conductivity type by the STI or LOCOS technology. Ions are implanted into the semiconductor substrate SB, thereby forming a well WL containing an impurity of the second conductivity type at a predetermined concentration. A region of the semiconductor substrate SB where no ions are implanted becomes a semiconductor region SR containing an impurity of the first conductivity type at a predetermined concentration. Next, in the step shown in FIG. 3B, a resist pattern having an opening corresponding to a region where a holding capacitor 414 or 415 should be formed is formed. Ions are implanted using the resist pattern as a mask, thereby forming a lower electrode 82 containing the impurity of the first conductivity type at a concentration higher than the well WL. At this time, the lower electrode 82 can be formed in the region defined by the element isolation portion 61. An insulating film 10 covering the entire surfaces of a pixel region as a prospective pixel unit 100 and a peripheral circuit region as a prospective peripheral circuit unit 700 is formed on the semiconductor substrate SB. The insulating film 10 is, for example, a silicon oxide film formed by a thermal oxidation method. Predetermined regions of the insulating film 10 become the gate insulating film and the insulating film of the capacitive element portion.

In the step shown in FIG. 3B, a resist pattern RP1 covering the entire surfaces of the regions where the pixel unit 100 and the peripheral circuit unit 700 should be formed and having an opening corresponding to a region where the holding capacitor 414 or 415 should be formed is formed on the insulating film 10. Nitriding processing is performed using the resist pattern RP1 as a mask, thereby forming a nitrided insulating film 80. The nitriding processing is performed by, for example, an ion implantation method or plasma nitriding method, thereby forming a nitrided silicon oxynitride film.

The plasma nitriding processing conditions are, for example:

RF power: 2.45 GHz 500 W

gas: N₂, Ar

pressure: 0.05 to 5 Torr

processing time: 10 to 150 sec

stage temperature: 20 to 100° C.

After the plasma nitriding processing, the resist pattern RP1 is removed, and post-nitriding annealing is performed. The post-nitriding annealing conditions are, for example:

temperature: 900 to 1,100° C.

gas: O₂

pressure: 0.5 to 5 Torr

processing time: 5 to 30 sec

In the step shown in FIG. 3C, a resist pattern RP2 is formed on the insulating film 10 and the insulating film 80, which cover the pixel region and the peripheral circuit region. At this time, the resist pattern RP2 covers the entire surface of the region when the pixel unit 100 should be formed. The resist pattern has openings in regions where the peripheral circuit unit 700 and the holding capacitors 414 and 415 should be formed. Even in the region where the peripheral circuit unit 700 is to be formed, a portion not to be nitrided is masked by the resist. Nitriding is selectively performed using the resist pattern RP2 as a mask, thereby forming a gate insulating film 50. The nitrided gate insulating film 50 is, for example, a silicon oxynitride film nitrided by the plasma nitriding method. The insulating film 80 is nitrided again together and therefore contains nitrogen atoms at a density higher than the gate insulating film 50. The plasma nitriding processing conditions are the same as those in, for example, forming the insulating film 80. Next, the resist pattern RP2 is removed, and post-nitriding annealing is performed. The post-nitriding annealing conditions are the same as those in, for example, forming the insulating film 80.

In the step shown in FIG. 3D, a polysilicon film to be formed as an electrodes is formed on the semiconductor substrate SB. A resist pattern (not shown) having a pattern corresponding to regions where gate electrodes 21 and 51 and an upper electrode 81 should be formed is formed on the polysilicon film. By masking using the resist pattern, the gate electrode 21 of a transfer transistor 2 in the pixel unit 100 and the gate electrode 51 of a MOS transistor in the peripheral circuit unit 700 are selectively formed. Simultaneously, electrodes such as the upper electrode 81 in the holding capacitor 414 or 415 are selectively formed. A resist pattern (not shown) covering the entire surfaces of the region as the prospective peripheral circuit unit 700 and the holding capacitors 414 and 415 is formed on the semiconductor substrate SB, the gate electrode 21, the gate electrode 51, and the upper electrode 81. An opening pattern corresponding to the region where the photoelectric converter 1 in the pixel unit 100 should be formed is formed in the resist pattern. Ions are implanted into the pixel region as the prospective pixel unit 100 in the semiconductor substrate SB using the opening pattern and the gate electrode 21 as a mask, thereby forming a charge accumulation region 11 containing the impurity of the first conductivity type.

After that, a resist pattern (not shown) is formed on the semiconductor substrate SB, the gate electrode 21, the gate electrode 51, and the upper electrode 81. A first opening pattern corresponding to a charge-voltage converter FD and a second opening pattern corresponding to source and drain regions 52 and 53 of the MOS transistor are formed in the resist pattern. Ions are implanted into the pixel region as the prospective pixel unit 100 in the semiconductor substrate SB using the first opening pattern and the gate electrode 21 as a mask, thereby forming the charge-voltage converter FD containing the impurity of the first conductivity type. In addition, ions are implanted into the peripheral circuit region as the prospective peripheral circuit unit 700 in the semiconductor substrate SB using the second opening pattern (not shown) and the gate electrode 51 as a mask. With this ion implantation, the source and drain regions 52 and 53 of the MOS transistor, which contain the impurity of the first conductivity type at a low concentration, are formed. After that, a resist pattern (not shown) having an opening pattern corresponding to a region where a protection region 12 should be formed is formed on the semiconductor substrate SB, the gate electrode 21, the gate electrode 51, and the upper electrode 81. Ions are implanted into the charge accumulation region 11 of the semiconductor substrate SB using the resist pattern (not shown) and the gate electrode 21 as a mask, thereby forming the protection region 12 containing the impurity of the second conductivity type at a high concentration.

In the step shown in FIG. 3E, an insulating film 30 is formed so as to cover the semiconductor substrate SB, the gate electrode 21 in the pixel unit 100, the gate electrode 51 in the peripheral circuit unit 700, and the upper electrode 81 in the holding capacitor 414 or 415. The insulating film 30 is formed from, for example, a silicon nitride film by the low pressure CVD technology (low pressure CVD method). The insulating film 30 formed by the low pressure CVD technology is known to be advantageous because, for example, films formed on different portions such as the semiconductor substrate SB and the side walls of the gate electrodes 21, 51, and 81 have almost the same thickness, and the film thickness uniformity is excellent. The insulating film 30 can have a film thickness of, for example, 40 to 55 nm considering that it functions as the anti-reflection film for preventing reflection of light by the light-receiving surface of the photoelectric converter 1. An insulating film (another insulating film) 40 is formed so as to cover the insulating film 30. The insulating film 40 is formed from, for example, a silicon oxide film.

In the step shown in FIG. 3F, a resist pattern RP3 covering the pixel region as the prospective pixel unit 100 and having an opening pattern corresponding to a region where the peripheral circuit unit 700 is to be formed and to the holding capacitors 414 and 415 is formed on the insulating film 40. Etching is performed using the resist pattern RP3 as a mask. More specifically, the insulating films 30 and 40 are etched so as to leave portions covering the side walls of the gate electrode 51 and the upper electrode 81. In this way, the insulating films 30 and 40 in the pixel unit 100 are formed, and side wall spacers 56 each including a first insulating film 54 and a second insulating film 55 are formed. The first insulating film 54 is a portion of the insulating film 30 remaining without being etched in each of the peripheral circuit unit 700 and the upper electrode 81. The second insulating film 55 is a portion of the insulating film 40 remaining without being etched in each of the peripheral circuit unit 700 and the upper electrode 81.

In the step shown in FIG. 3G, first, the resist pattern RP3 is removed. A resist pattern having an opening pattern corresponding to the semiconductor region 52 is formed. Ions are implanted by self alignment using the opening pattern, and using the gate electrode 51 and the side wall spacer 56 as a mask. The semiconductor region 52 containing the impurity of the first conductivity type at a high concentration is thus formed. The semiconductor region 52 functions as a source electrode or drain electrode of the MOS transistor.

After that, an interlayer insulating film (not shown) is formed so as to cover the insulating film 40 in the pixel unit 100 and the semiconductor substrate, the gate electrode 51, the upper electrode 81, and the side wall spacers 56 in the peripheral circuit unit 700 and the holding capacitor 414 or 415. Subsequently, although not illustrated, contact holes that expose the charge-voltage converter FD and the semiconductor region 52 are formed in the interlayer insulating film and then filled with a metal to form contact plugs. In addition, metal interconnections, color filters, microlenses, and the like are formed, thus completing a solid-state image sensor.

As described above, in the solid-state image sensor 800, since the gate insulating film 20 of the MOS transistor 2 in the pixel unit 100 is formed from a silicon oxide film, 1/f noise can be suppressed. The gate insulating film 50 of the MOS transistor in the peripheral circuit unit 700 is formed from a silicon oxynitride film nitrided to an appropriate concentration to suppress degradation in characteristic. As a result, the driving capability of the MOS transistor can be improved by thinning the gate insulating film. In addition, since the insulating film 80 of the holding capacitor 414 or 415 is formed from a silicon oxynitride film nitrided to a concentration higher than the gate electrode, the capacitance per area can be increased, and the area of the holding capacitors 414 and 415 can be made small. Insulating film nitriding processing is performed for the insulating film 80 first. However, the nitriding processing may be performed first for the gate insulating film 50 and the insulating film 80, and then for the insulating film 80 using a mask having an opening.

Note that in the solid-state image sensor 800, the peripheral circuit unit 700 may include an A/D conversion circuit at the subsequent stage of the column amplifier unit AM in each column or at the preceding stage of the output amplifier block 450. In addition, the peripheral circuit unit 700 may include an arithmetic circuit capable of, for example, adding and averaging signals.

### Second Embodiment

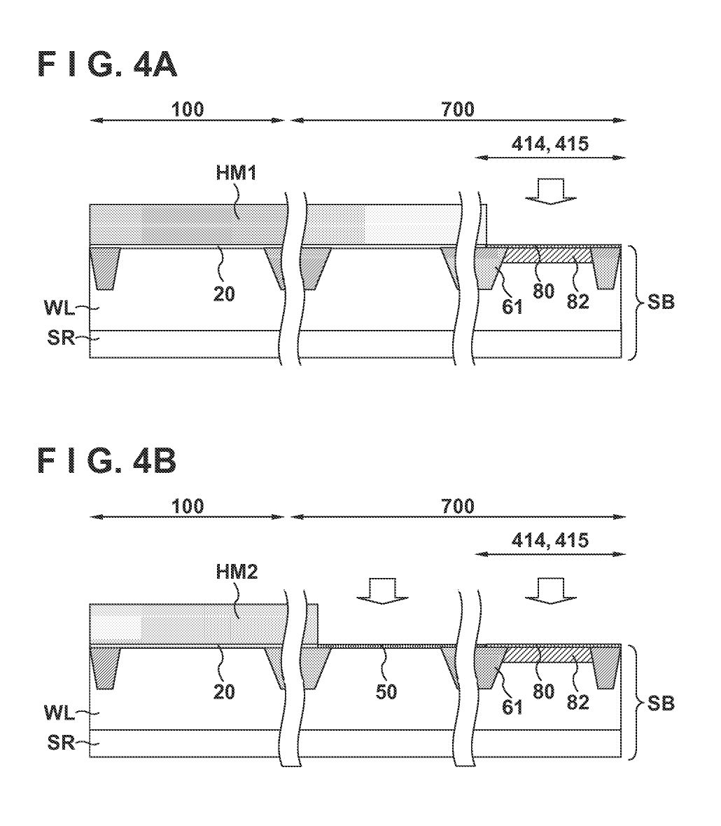

A method of manufacturing a solid-state image sensor 800 according to the second embodiment of the present invention will be described next with reference to FIGS. 4A and 4B. FIGS. 4A and 4B are sectional views showing the steps in the method of manufacturing the solid-state image sensor 800 according to this embodiment of the present invention. Points different from the first embodiment will mainly be explained. The method of manufacturing the solid-state image sensor 800 according to this embodiment is different from that of the first embodiment in the steps shown in FIGS. 3B and 3C. The step shown in FIG. 4A is performed next to the step shown in FIG. 3A of the first embodiment.

In the step shown in FIG. 4A, a hard mask pattern HM1 covering the entire surfaces of a pixel region where a pixel unit 100 is to be formed and a region where a peripheral circuit unit 700 is to be formed and having an opening pattern corresponding to a region where a holding capacitor 414 or 415 is to be formed is formed on an insulating film 10. The hard mask pattern HM1 is formed from, for example, a polysilicon film. Nitriding processing is performed using the hard mask pattern HM1 as a mask, thereby forming an insulating film 80. The insulating film 80 is, for example, a silicon oxynitride film nitrided by a plasma nitriding method.

The plasma nitriding processing conditions are, for example:

RF power: 2.45 GHz 1,500 W

gas: N₂, Ar

pressure: 0.05 to 5 Torr

processing time: 10 to 150 sec

stage temperature: 100 to 400° C.

After the plasma nitriding processing, the hard mask pattern HM1 is removed, and post-nitriding annealing is performed. The post-nitriding annealing conditions are, for example:

temperature: 900 to 1,100° C.

gas: O₂

pressure: 0.5 to 5 Torr

processing time: 5 to 30 sec

In the step shown in FIG. 4B, a hard mask pattern HM2 covering the entire surface of the pixel region where the pixel unit 100 is to be formed and having openings in the region where the peripheral circuit unit 700 is to be formed and the region where the holding capacitor 414 or 415 is to be formed is formed on the insulating film 10. Even in the peripheral circuit region 700, a portion not to be nitrided is masked. The hard mask pattern HM2 is formed from, for example, a polysilicon film. The insulating film 10 is nitrided using the hard mask pattern HM2 as a mask, thereby forming a gate insulating film 50. The gate insulating film 50 is, for example, a silicon oxynitride film nitrided by the plasma nitriding method. At this time, the insulating film 80 is also nitrided again and therefore contains nitrogen atoms at a density higher than the gate insulating film 50. The plasma nitriding processing conditions are the same as those in, for example, forming the insulating film 80. After that, the hard mask pattern HM2 is removed. After the step shown in FIG. 4B is performed, the same steps as those shown in FIGS. 3D to 3G of the first embodiment are performed.

In general, when the plasma nitriding method is performed under the conditions of high RF power and high stage temperature, the concentration of nitrogen contained in the gate insulating film can be raised. In this embodiment using a hard mask pattern, the RF power and stage temperature can be set higher than in the first embodiment using a resist pattern.

For this reason, when a hard mask pattern is used, various plasma nitriding conditions can be applied to the method of manufacturing the solid-state image sensor.

### Third Embodiment

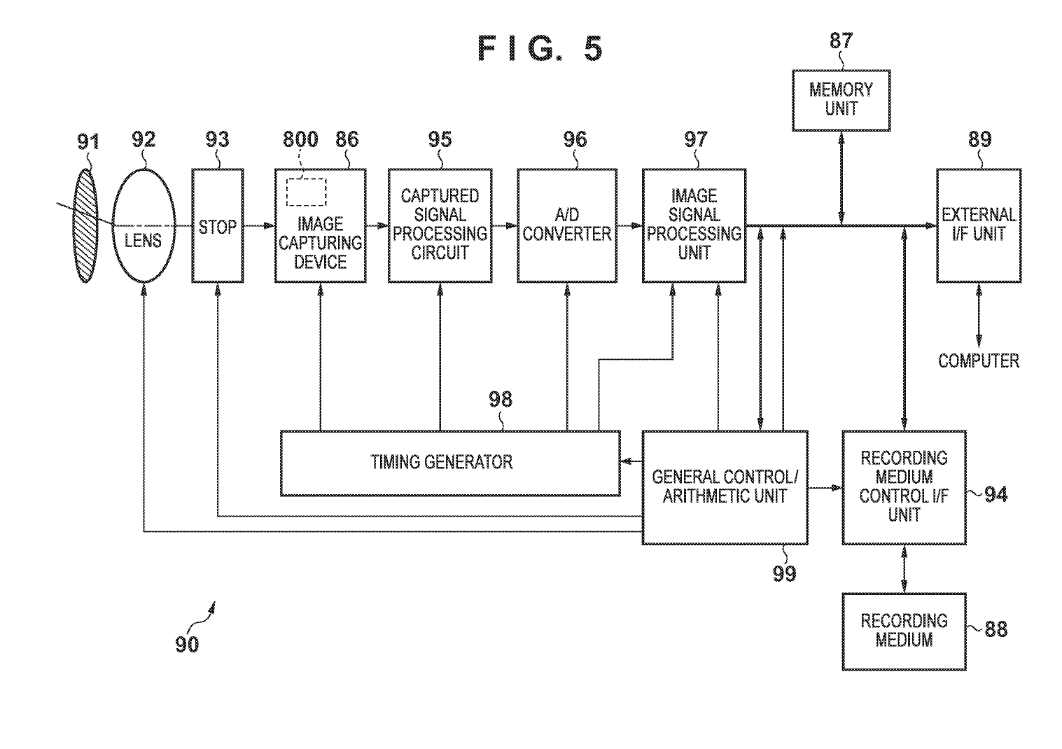

FIG. 5 illustrates an example of an image capturing system to which a solid-state image sensor according to the present invention is applied. An image capturing system 90 includes an optical system, an image capturing device 86, and a signal processing unit. The optical system includes a shutter 91, a lens 92, and a stop 93, and forms an image of an object on the solid-state image sensor 800 of the image capturing device 86. The signal processing unit includes a captured signal processing circuit 95, an A/D converter 96, an image signal processing unit 97, a memory unit 87, an external I/F unit 89, a timing generator 98, a general control/arithmetic unit 99, a recording medium 88, and a recording medium control I/F unit 94. Note that the recording medium 88 may be provided detachably or externally. The operation of each unit will be described next. The solid-state image sensor 800 converts a formed object image into an electrical signal. The image capturing device 86 reads out the image signal from the solid-state image sensor 800 and outputs it. The captured signal processing circuit 95 is connected to the image capturing device 86 and processes a signal output from it. The A/D converter 96 is connected to the captured signal processing circuit 95 and converts the image signal (analog signal) output from the captured signal processing circuit 95 into an image signal (digital signal). The image signal processing unit 97 is connected to the A/D converter 96 and performs various kinds of arithmetic processing such as correction for the image signal (digital signal) output from the A/D converter 96, thereby generating image data. Note that the captured signal processing circuit 95, the A/D converter 96, and the image signal processing unit 97 are included in the image capturing device 86 in some cases. The image data is provided to the memory unit 87, the external I/F unit 89, the general control/arithmetic unit 99, the recording medium control I/F unit 94, and the like.

The memory unit 87 is connected to the image signal processing unit 97 and stores the image data output from it. The external I/F unit 89 is connected to the image signal processing unit 97. The image data output from the image signal processing unit 97 is thus transferred to an external apparatus (for example, personal computer) via the external I/F unit 89. The timing generator 98 is connected to the image capturing device 86, the captured signal processing circuit 95, the A/D converter 96, and the image signal processing unit 97. The timing generator 98 thus supplies a timing signal to the image capturing device 86, the captured signal processing circuit 95, the A/D converter 96, and the image signal processing unit 97. The image capturing device 86, the captured signal processing circuit 95, the A/D converter 96, and the image signal processing unit 97 then operates in synchronism with the timing signal. The general control/arithmetic unit 99 is connected to the timing generator 98, the image signal processing unit 97, and the recording medium control I/F unit 94 and generally controls them. The recording medium 88 may detachably be connected to the recording medium control I/F unit 94. Image data output from the image signal processing unit 97 is thus recorded in the recording medium 88 via the recording medium control I/F unit 94. With the above-described arrangement, when an image signal output from the solid-state image sensor 800, which includes reduced noise, is used, a satisfactory image (image data) can be obtained.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-109387, filed May 23, 2013, which is hereby incorporated by reference herein in its entirety.

What is claimed is:

1. A solid-state image sensor comprising:
a pixel unit arranged on a semiconductor substrate and including a plurality of photoelectric converters, and a peripheral circuit unit arranged on the semiconductor substrate and including a MOS transistor and a capacitive element portion,
wherein a gate insulating film of the MOS transistor in the peripheral circuit unit and an insulating film between facing electrodes of the capacitive element portion are nitrided, and
a density of nitrogen atoms in the nitrided insulating film of the capacitive element portion is higher than the density of the nitrogen atoms in the nitrided insulating film of the MOS transistor in the peripheral circuit unit.

2. The sensor according to claim 1, wherein the gate insulating film of the MOS transistor in the pixel unit is not nitrided.

3. The sensor according to claim 1, wherein the facing electrodes of the capacitive element portion include a lower electrode formed by implanting an impurity into a region sandwiched by element isolation portions configured to isolate the capacitive element portion from other elements.

4. The sensor according to claim 3, wherein a gate electrode of the MOS transistor in the peripheral circuit unit and an electrode facing the lower electrode of the capacitive element portion are formed from polysilicon.

5. The sensor according to claim 3, wherein a side wall spacer is formed on each of a gate electrode of the MOS transistor in the peripheral circuit unit and an electrode facing the lower electrode of the capacitive element portion.

6. An image capturing system comprising:
a solid-state image sensor defined in claim 1; and
a signal processing circuit configured to process an output signal from the solid-state image sensor.

7. A solid-state image sensor comprising:
a pixel unit arranged on a semiconductor substrate and including a plurality of photoelectric converters, and a peripheral circuit unit arranged on the semiconductor substrate and including a MOS transistor and a capacitive element portion,
wherein a gate insulating film of the MOS transistor in the peripheral circuit unit and an insulating film between facing electrodes of the capacitive element portion are nitrided,
the gate insulating film of the MOS transistor in the pixel unit is not nitrided, and
a density of nitrogen atoms in the nitrided insulating film of the capacitive element portion is higher than the density of the nitrogen atoms in the nitrided insulating film of the MOS transistor in the peripheral circuit unit.

8. An image capturing system comprising:
a solid-state image sensor defined in claim 7; and
a signal processing circuit configured to process an output signal from the solid-state image sensor.

9. A method of manufacturing a solid-state image sensor comprising a pixel unit arranged on a semiconductor substrate and including a plurality of photoelectric converters, and a peripheral circuit unit arranged on the semiconductor substrate and including a MOS transistor and a capacitive element portion, the method comprising:
forming a lower electrode by implanting an impurity into a region of the semiconductor substrate where the capacitive element portion should be formed;
forming an insulating film covering a region of the semiconductor substrate where a pixel region should be formed and a region where a peripheral circuit region should be formed;
selectively nitriding the insulating film in the region where the capacitive element portion should be formed; and
selectively nitriding the insulating film in the region where the capacitive element portion should be formed and the region where the peripheral circuit unit should be formed.

10. The method according to claim 9, wherein the selectively nitriding the insulating film in the region where the capacitive element portion should be formed is performed before the selectively nitriding the insulating film in the region where the capacitive element portion should be formed and the region where the peripheral circuit unit should be formed.

11. The method according to claim 9, wherein the selectively nitriding the insulating film in the region where the capacitive element portion should be formed and the region where the peripheral circuit unit should be formed is performed before the selectively nitriding the insulating film in the region where the capacitive element portion should be formed.

12. The method according to claim 9, wherein the nitriding is performed by one of an ion implantation method and a plasma nitriding method.

13. The method according to claim 9, further comprising forming, by polysilicon, a gate electrode of the MOS transistor in each of the pixel unit and the peripheral circuit unit and an electrode facing the lower electrode of the capacitive element portion.

14. The method according to claim 9, wherein the nitriding is performed by masking using a hard mask.
